(19) United States
(12) Patent Application Publication
(10) Pub. No.: US 2013/0008784 A1
(43) Pub. Date: Jan. 10, 2013

(54) COCRPT-BASED ALLOY SPUTTERING TARGETS WITH COBALT OXIDE AND NON-MAGNETIC OXIDE AND MANUFACTURING METHODS THEREOF

(75) Inventors: Wen-Tsang LIU, Tainan (TW); Kun-Ming Chen, Tainan (TW); Yung-Chun Hsueh, Tainan (TW); Hoa-Chia Liao, Tainan (TW)

(73) Assignee: SOLAR APPLIED MATERIALS TECHNOLOGY CORP., Tainan (TW)

(21) Appl. No.: 13/178,594

(22) Filed: Jul. 8, 2011

(51) Int. Cl. C23C 14/08; B22F 3/12; C23C 14/34

(52) U.S. Cl. 204/298.13; 419/19

(57) ABSTRACT

Provided is a CoCrPt-based alloy sputtering target containing cobalt (Co), chromium (Cr), platinum (Pt), cobalt oxide and non-magnetic oxide composition, wherein the lengths of ceramic phases of Cr₂O₃ and Co(Cr)—X—O formed in the sputtering targets are respectively less than 3 μm (“X” represents the metal element of the non-magnetic oxide). The sputtering target is obtained via controlling suitable composition proportion of the prealloy powder with Cr and the sintering factor to decrease the size of ceramic phases of Cr₂O₃ and Co(Cr)—X—O. Sputtering targets made by the methods of the present invention decrease the arcing effects and unnecessary formation of particles upon sputtering in addition to making the components of the sputtering targets distribute more uniformly therein.

### BACKGROUND OF THE INVENTION

1. Field of the Invention

The present invention relates to a sputtering target containing cobalt oxide and non-magnetic oxide and a method for producing the same, and more particularly to a method for producing a sputtering target containing uniformly distributed components and decreasing arcing and particles during sputtering.

2. Description of the Prior Arts

Generally, sputtering targets containing cobalt-chromium-platinum-based alloy (CoCrPt-based alloy) are used to form recording layers in perpendicular magnetic recording media. In industry, the recording layers are formed by sputtering, and oxygen is usually used as reactive gas during such sputtering processes. However, if excessive oxygen is used, the highly active metals in the targets easily react with oxygen and result in arcing effects and unnecessary formation of particles.

For solving the foregoing problems, some people try to add cobalt oxide into the targets. Cobalt oxide can be broken down into cobalt atoms and oxygen radicals. Such oxygen free radicals can react with active metals and be deposited on substrates. The oxygen radicals provide higher free energy than oxygen atoms. Also, the oxygen free radicals easily make produced oxides segregate into the grain boundary of the microstructure of metal substances (i.e. CoCrPt alloy) in magnetic recording media in order to avoid signal interference. Thus, there is no need to use oxygen as reaction gas. However, as known from Ellingham diagram and relevant experiment results, cobalt oxide can cause oxidation-reduction with chromium of the targets and form coaser strip clusters of chromium oxide (such as Cr₂O₃ clusters). Such clusters often make components ununiformly distributed in the targets and cause arcing effects and formation of particles during sputter deposition.

WIPO Patent No. 2007/116834 discloses a method for producing Co-based sintered alloy used for magnetic recording film, which includes mixing cobalt-chromium prealloy powder containing 50 to 70 at % of chromium with platinum powder, cobalt powder and non-magnetic oxide powder to form a powder mixture, which consists of 2 to 15 mol % of non-magnetic oxide, 3 to 20 mol % of chromium and 5 to 30 mol % of platinum, and sintering the powder mixture under sintering process. The produced target used for sputtering processes can generate fewer particles, and the number of chromium oxide clusters having an absolute maximum length of more than 5 μm is not more than 500 clusters/mm². The non-magnetic oxide is SiO₂, TiO₂, Ta₂O₅, Al₂O₃, MgO, ThO₂, ZrO₂, CeO₂, Y₂O₃ or a combination thereof.

Nevertheless, using the prealloy powder described above as raw material to produce CoCrPt-based alloy sputtering targets cannot effectively avoid the generation of chromium oxide clusters, and thus the taught method cannot resolve the problems of the current technology.

To overcome the shortcomings, the present invention provides a CoCrPt-based alloy sputtering target with cobalt oxide and non-magnetic oxide to mitigate or obviate the aforementioned problems.

### SUMMARY OF THE INVENTION

The main objective of the present invention provides a CoCrPt-based alloy sputtering target with cobalt oxide and non-magnetic oxide, which is made via controlling suitable composition proportion of the prealloy powder with Cr and the sintering factors. The sputtering target in accordance with the present invention can overcome arcing effects and unnecessary formation of particles during sputtering.

To achieve the objective, the CoCrPt-based alloy sputtering target with cobalt oxide and non-magnetic oxide in accordance with the present invention comprises cobalt, chromium, platinum, cobalt oxide and non-magnetic oxide composition, wherein the lengths of ceramic phases of Cr₂O₃ and Co(Cr)—X—O formed in the sputtering target are respectively less than 3 μm, wherein X represents the metal element of the non-magnetic oxide.

In another aspect, the present invention provides a manufacturing method for producing the sputtering target described above, which comprises steps of:
(i) providing a raw material essentially consisting of prealloy powder containing 20 to 80 at % of chromium, cobaltous oxide CoO) powder and oxide mixture, wherein the oxide mixture contains one or more non-magnetic oxide powder, cobalt powder and platinum powder;
(ii) compacting the raw material to form a green compact;
(iii) sintering the green compact to obtain the CoCrPt-based alloy sputtering target with cobalt oxide and non-magnetic oxide.

In accordance with the present invention, “essentially consisting of ” means a material mainly consists of the specified substance, whereas the material also includes other unavoidable impurities. Specifically, the raw material mainly consists of prealloy powder containing 20 to 80 at % of chromium, cobalt oxide powder and oxide mixture, wherein the raw material contains other unavoidable impurities

The sputtering target in accordance with the present invention is obtained via controlling suitable composition proportion of the prealloy powder with Cr and the sintering factors to decrease the size of ceramic phases of Cr₂O₃ and Co(Cr)—X—O. The sputtering target made by the methods of the present invention decreases the arcing effects and unnecessary formation of particles upon sputtering in addition to making the components of the sputtering target distribute more uniformly therein. Also, the sputtering targets in accordance with the present invention are useful for applying to recording layers of magnetic recording media.

Other objectives, advantages and novel features of the invention will become more apparent from the following detailed description when taken in conjunction with the accompanying drawings.

### BRIEF DESCRIPTION OF THE DRAWINGS

FIG. 1 is a metallographic microscope image of a conventional sputtering target in comparative example 1 in accordance with the prior art.

FIG. 2 is a metallographic microscope image of a conventional sputtering target in comparative example 2 in accordance with the prior art.

FIG. 3 is a metallographic microscope image of a conventional sputtering target in comparative example 3 in accordance with the prior art.

FIG. 4 is a metallographic microscope image of a sputtering target in example 1 in accordance with the present invention.

### DETAILED DESCRIPTION OF THE PREFERRED EMBODIMENTS

A CoCrPt-based alloy sputtering target with cobalt oxide and non-magnetic oxide in accordance with the present invention comprises cobalt, chromium, platinum, cobalt oxide and non-magnetic oxide composition, wherein the lengths of ceramic phases of Cr₂O₃ and Co(Cr)—X—O formed in the sputtering target are respectively less than 3 μm (“x” represents the metal element of the non-magnetic oxide).

In a preferred embodiment, the non-magnetic oxide composition is selected from the group consisting of silicon dioxide (SiO₂), titanium dioxide (TiO₂), tantalum dioxide (Ta₂O₅) and a combination thereof.

In a preferred embodiment, the CoCrPt-based alloy sputtering target further comprises at least one element selected from the group consisting of tantalum (Ta), copper (Cu), boron (B) and a combination thereof.

A method for manufacturing a CoCrPt-based alloy sputtering target with cobalt oxide and non-magnetic oxide in accordance with the present invention comprises steps of:
(i) providing a raw material essentially consisting of prealloy powder containing 20 to 80 at % of chromium, cobaltous oxide (CoO) powder and oxide mixture, wherein the oxide mixture contains one or more non-magnetic oxide powder, cobalt powder and platinum powder;
(ii) compacting the raw material to form a green compact;
(iii) sintering the green compact to obtain the CoCrPt-based alloy sputtering target with cobalt oxide and non-magnetic oxide.

According to the present invention, the prealloy powder includes powder of a substance selected from the group consisting of: Co—Cr alloy, Cr—Pt alloy, Co—Cr—Pt alloy and a combination thereof.

According to the present invention, the step of sintering the green compact to obtain the sputtering target includes: sintering the green compact at the temperature of between 850° C. and 1050° C. to obtain the CoCrPt-based alloy sputtering target with cobalt oxide and non-magnetic oxide.

In a preferred embodiment, the non-magnetic oxide powder is powder of a substance selected from the group consisting of SiO₂, TiO₂, Ta₂O₅ and a combination thereof.

In a preferred embodiment, the CoCrPt-based alloy sputtering target further comprises at least one element selected from the group consisting of tantalum (Ta), copper (Cu), boron (B) and a combination thereof.

The present invention is further illustrated by the following examples; it should be understood that the examples and embodiments described herein are for illustrative purposes only and should not be construed as limiting the embodiments set forth herein.

### EXAMPLES

### Comparative Example 1

### Producing a Sputtering Target of 75Co-12Cr-5Pt-8(TiO₂) on a Basis of Atomic Percentage Ratio

88.4 grams of Co powder (average particle size: 7 μm), 18.8 grams of Cr powder (average particle size: 20 μm), 19.5 grams of Pt powder (average particle size: 8 μm) and 12.78 grams of TiO₂ powder (average particle size: 10 μm) were mixed and milled by automatic milling machine for 30 minutes. Then, those powders were sieved with a 60 mesh. The powders passing through 60 mesh sieve were mixed homogeneously to form a mixture. The mixture was well-distributed into a graphite mold and compacted to form a green compact under a hydraulic press of 300 psi. The graphite mold with the green compact was put into a hot-pressing furnace and the green compact was sintered at 1150° C. under 362 bar for 180 minutes to obtain a sputtering target.

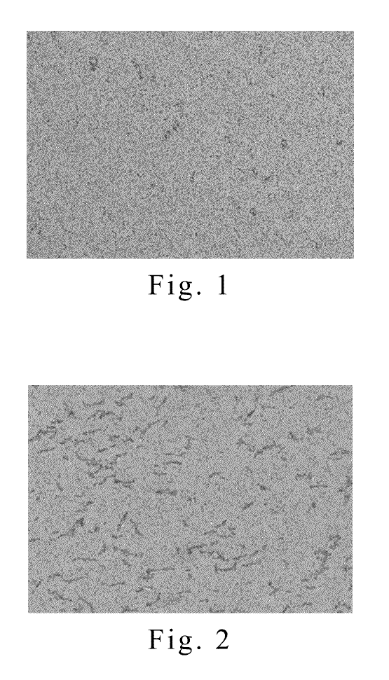

FIG. 1 shows a metallographic microscope image of the sputtering target of the comparative example 1 taken by scanning electron microscope (Hitachi N-3400 SEM), and it shows obviously that the sputtering target only contains ceramic phase of titanium without chromium oxide clusters.

### Comparative Example 2

### Producing a Sputtering Target of 54Co-17Cr-18Pt-4(TiO₂)-7CoO on a Basis of Atomic Percentage Ratio

63.64 grams of Co powder (average particle size: 7 μm), 17.68 grams of Cr powder (average particle size: 20 μm), 70.24 grams of Pt powder (average particle size: 8 μm), 6.4 grams of TiO₂ powder (average particle size: 10 μm) and 10.5 grams of CoO powder (average particle size: 8 μm) were mixed and milled by automatic milling machine for 30 minutes. Then, those powders were sieved with a 60 mesh. The powders passing through the 60 mesh sieve were mixed homogeneously to form a mixture. The mixture was well-distributed into a graphite mold and compacted to form a green compact under a hydraulic press of 300 psi. The graphite mold with the green compact was put into a hot-pressing furnace and the green compact was sintered at 1150° C. under 362 bar for 180 minutes to obtain a sputtering target.

FIG. 2 shows a metallographic microscope image of the sputtering target of the comparative example 2 taken by scanning electron microscope (Hitachi N-3400 SEM) and analyzed by image analyzer software (Image-Pro 6.3). Then, the average and standard variation of the size of the ceramic phase of Cr₂O₃ and Cr—Ti—O are calculated by statistics software. FIG. 2 shows obviously that the sputtering target forms many Cr₂O₃ clusters. In addition, the ceramic phase of Cr₂O₃ and Cr—Ti—O having an average length of 3.64±2.89 μm (more than 3 μm).

### Comparative Example 3

### Producing a Sputtering Target of 64Co-12Cr-7Pt-8(TiO₂)-9CoO on a Basis of Atomic Percentage Ratio

63.86 grams of Co powder (average particle size: 7 μm), 23.94 grams of 45 at % Co-55 at % Cr prealloy powder (average particle size: 10-100 μm), 27.32 grams of Pt powder (average particle size: 8 μm), 12.76 grams of TiO₂ powder (average particle size: 10 μm) and 13.48 grams of CoO powder (average particle size: 8 μm) were mixed and milled by automatic milling machine for 30 minutes. Then, those powders were sieved with a 60 meshes. The powders passing through the 60-mesh sieve were mixed homogeneously to form a mixture. The mixture was well-distributed into a graphite mold and compacted to form a green compact under a hydraulic press under 300 psi. The graphite mold with the green compact was put into a hot-pressing furnace and the green compact was sintered at 1150° C. under 362 bar for 180 minutes to obtain a sputtering target.

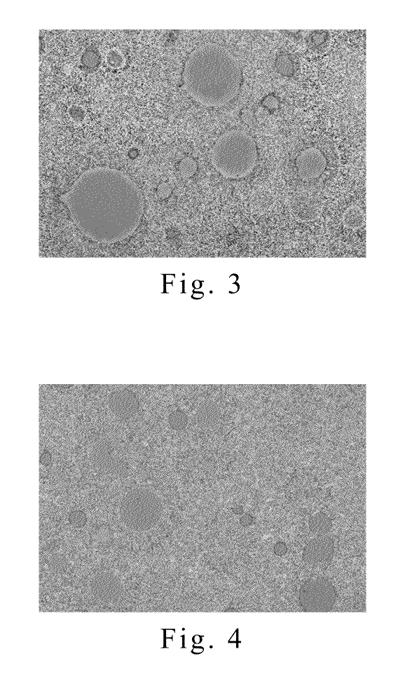

FIG. 3 shows a metallographic microscope image of the sputtering target of the comparative example 3 taken by scanning electron microscope (Hitachi N-3400 SEM) and analyzed by image analyzer software (Image-Pro 6.3). Then, the average and standard variation of the size of the ceramic phase of Cr₂O₃ and Cr—Ti—O are calculated by statistics software. FIG. 3 shows obviously that the sputtering target forms many coaser Cr₂O₃ clusters. In addition, the ceramic phase of Cr₂O₃ and Cr—Ti—O having an average length of 1.97±1.51 μm (still possibly more than 3 μm).

### Example 1

### Producing a Sputtering Target of 64Co-12Cr-7Pt-8(TiO₂)-9CoO on a Basis of Atomic Percentage Ratio

63.86 grams of Co powder (average particle size: 7 μm), 23.94 grams of 45 at % Co-55 at % Cr prealloy powder (average particle size: 10-100 μm), 27.32 grams of Pt powder (average particle size: 8 μm), 12.76 grams of TiO₂ powder (average particle size: 10 μm) and 13.48 grams of CoO powder (average particle size: 8 μm) were mixed and milled by automatic milling machine for 30 minutes. Then, those powders were sieved with a 60 mesh. The powders passing through 60 mesh sieve were mixed homogeneously to form a mixture. The mixture was well-distributed into a graphite mold and compact to form a green compact under a hydraulic press under 300 psi. The graphite mold with the green compact was put into a hot-pressing furnace and the green compact was sintered at 1050° C. under 362 bar for 180 minutes to obtain a sputtering target.

FIG. 4 shows a metallographic microscope image of the sputtering target of the example 1 taken by scanning electron microscope (Hitachi N-3400 SEM) and analyzed by image analyzer software (Image-Pro 6.3). Then, the average and standard variation of the size of the ceramic phase of Cr₂O₃ and Cr—Ti—O are calculated by statistics software. FIG. 4 shows obviously that the sputtering target forms fewer Cr₂O₃ aggregates and contains the ceramic phase of Cr₂O₃ and Cr—Ti—O having an average length of 1.29±0.94 μm (less than 3 μm).

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A CoCrPt-based alloy sputtering target with cobalt oxide and non-magnetic oxide comprising: cobalt, chromium, platinum, cobalt oxide and non-magnetic oxide composition, wherein the lengths of ceramic phases of Cr₂O₃ and Co(Cr)—X—O formed in the sputtering target are respectively less than 3 μm, wherein X represents the metal element of the non-magnetic oxide.

2. The CoCrPt-based alloy sputtering target with cobalt oxide and non-magnetic oxides as claimed in claim 1, wherein the non-magnetic oxide composition is selected from the group consisting of silicon dioxide (SiO₂), titanium dioxide (TiO₂), tantalum dioxide (Ta₂O₅) and a combination thereof.

3. The CoCrPt-based alloy sputtering target with cobalt oxide and non-magnetic oxides as claimed in claim 1, which further comprises Ta, Cu, B or a combination thereof.

4. The CoCrPt-based alloy sputtering target with cobalt oxide and non-magnetic oxides as claimed in claim 2, which further comprises Ta, Cu, B or a combination thereof.

5. A method for manufacturing a CoCrPt-based alloy sputtering target with cobalt oxide and non-magnetic oxide comprising steps of:
(i) providing a raw material essentially consisting of prealloy powder containing 20 to 80 at % of chromium, cobaltous oxide powder and oxide mixture, wherein the oxide mixture contains one or more non-magnetic oxide powder, cobalt powder and platinum powder;
(ii) compacting the raw material to form a green compact;
(iii) sintering the green compact to obtain the CoCrPt-based alloy sputtering target with cobalt oxide and non-magnetic oxide.

6. The method as claimed in claim 5, wherein the prealloy powder includes powder of a substance selected from the group consisting of: Co—Cr alloy, Cr—Pt alloy, Co—Cr—Pt alloy and a combination thereof.

7. The method as claimed in claim 5, wherein the CoCrPt-based alloy sputtering target further comprises at least one element selected from the group consisting of: Ta, Cu, B and a combination thereof.

8. The method as claimed in claim 5, wherein the step of sintering the green compact to obtain the sputtering target includes: sintering the green compact at the temperature of between 850° C. and 1050° C. to obtain the CoCrPt-based alloy sputtering target with cobalt oxide and non-magnetic oxide.

9. The method as claimed in claim 5, wherein the non-magnetic oxide powder is powder of a substance selected from the group consisting of SiO₂, TiO₂, Ta₂O₅ and a combination thereof.

10. A CoCrPt-based alloy sputtering target with cobalt oxide and non-magnetic oxide, which is produced by the method according to claim 5.

11. The CoCrPt-based alloy sputtering target with cobalt oxide and non-magnetic oxides as claimed in claim 10, wherein the lengths of ceramic phases of Cr₂O₃ and Co(Cr)—X—O formed in the sputtering target are respectively less than 3 μm, wherein X represents the metal element of the non-magnetic oxide.

12. The CoCrPt-based alloy sputtering target with cobalt oxide and non-magnetic oxides as claimed in claim 10, wherein the non-magnetic oxide composition is selected from the group consisting of silicon dioxide(SiO₂), titanium dioxide(TiO₂), tantalum dioxide(Ta₂O₅) and a combination thereof.

13. The CoCrPt-based alloy sputtering target with cobalt oxide and non-magnetic oxides as claimed in claim 10, which further comprises Ta, Cu, B or a combination thereof.

14. A CoCrPt-based alloy sputtering target with cobalt oxide and non-magnetic oxide, which is produced by the method according to claim 6.

15. The CoCrPt-based alloy sputtering target with cobalt oxide and non-magnetic oxides as claimed in claim 14, wherein the lengths of ceramic phases of Cr₂O₃ and Co(Cr)—X—O formed in the sputtering target are respectively less than 3 μm, wherein X represents the metal element of the non-magnetic oxide.

16. The CoCrPt-based alloy sputtering target with cobalt oxide and non-magnetic oxides as claimed in claim 14, wherein the non-magnetic oxide composition is selected from the group consisting of silicon dioxide(SiO₂), titanium dioxide(TiO₂), tantalum dioxide(Ta₂O₅) and a combination thereof.

17. The CoCrPt-based alloy sputtering target with cobalt oxide and non-magnetic oxides as claimed in claim 14, which further comprises Ta, Cu, B or a combination thereof.

18. A CoCrPt-based alloy sputtering target with cobalt oxide and non-magnetic oxide, which is produced by the method according to claim 7.

19. The CoCrPt-based alloy sputtering target with cobalt oxide and non-magnetic oxides as claimed in claim 18, wherein the lengths of ceramic phases of Cr₂O₃ and Co(Cr)—X—O formed in the sputtering target are respectively less than 3 μm, wherein X represents the metal element of the non-magnetic oxide.

20. The CoCrPt-based alloy sputtering target with cobalt oxide and non-magnetic oxides as claimed in claim 18, wherein the non-magnetic oxide composition is selected from the group consisting of silicon dioxide(SiO₂), titanium dioxide(TiO₂), tantalum dioxide(Ta₂O₅) and a combination thereof.
